(19) United States
(12) Patent Application Publication
(10) Pub. No.: US 2020/0011911 A1
(43) Pub. Date: Jan. 9, 2020

(54) HIGH-PRECISION FREQUENCY MEASURING SYSTEM AND METHOD

(71) Applicant: NO. 24 RESEARCH INSTITUTE OF CHINA ELECTRONICS TECHNOLOGY GROUP CORPORATION, Chongqing (CN)

(72) Inventors: Yingtai LI, Chongqing (CN); Gangyi HU, Chongqing (CN); Luncai LIU, Chongqing (CN); Fan LIU, Chongqing (CN); Jian'an WANG, Chongqing (CN); Xin LEI, Chongqing (CN); Xiaozong HUANG, Chongqing (CN); Guoqiang WANG, Chongqing (CN); Jin ZHAO, Chongqing (CN); Jianzhuang LI, Chongqing (CN)

(73) Assignee: NO. 24 RESEARCH INSTITUTE OF CHINA ELECTRONICS TECHNOLOGY GROUP CORPORATION, Chongqing (CN)

(21) Appl. No.: 16/493,184

(22) PCT Filed: Jul. 21, 2017
(86) PCT No.: PCT/CN2017/093839

§ 371 Date: Sep. 11, 2019

(30) Foreign Application Priority Data
Apr. 13, 2017 (CN) 201710240279.4

(51) Int. Cl. G01R 23/02

(52) U.S. Cl. CPC G01R 23/02

(57) ABSTRACT

A high-precision frequency measuring system and method. The system includes: an analog-to-digital conversion module for receiving an analog intermediate frequency signal to convert the analog intermediate frequency signal into a digital intermediate frequency signal; a frequency mixing module for generating two orthogonal local carriers to convert the digital intermediate frequency signal to a digital baseband signal; an extraction filter module for performing low-pass filtering and extraction of the digital baseband signal, so as to reduce a data rate; a Fourier transform module for obtaining a frequency domain signal; a frequency measurement module for obtaining a first frequency measurement value; a scanning module for obtaining a scanned second frequency measurement value; and a selector for selecting either the first frequency measurement value or the second frequency measurement value as a result of frequency measurement. The system and method can improve the accuracy of frequency measurement.

### TECHNICAL FIELD

The present disclosure relates to the technical field of signal processing, in particular to a short data high-precision frequency measuring system and method based on digital signal processing.

### BACKGROUND

Parameter estimation is an important part of signal and information processing. It is also an active and rapidly developing research field in recent years. In the time series, the signal frequency is an important signal parameter. Measuring the sine wave frequency submerged in the noise is one of the most practical techniques in modern signal processing. It is the basis for testing all spectrum estimation performance, and is also the basis of signal processing technology. This technology has been widely used in radar, electronic countermeasures, sonar and other fields. The advancement of frequency measurement technology will inevitably promote the development of the above application fields. With the rapid development of modern communication and information processing technology, the research on frequency measurement technology will certainly raise higher requirements.

However, the traditional classical methods (i.e., frequency measuring methods) are based on the Discrete Fourier transform (DFT), and the discovery of the Fast Fourier Transform (FFT) has promoted the classical methods to be more widely used. However, the limitation of the classical method is that its measurement resolution is proportional to the data length. To increase the resolution, the data length must be increased.

### SUMMARY

The present disclosure provides a high-precision frequency measuring system and method for solving the problem of low accuracy of measuring short data.

The present disclosure provides a high-precision frequency measuring system, including: an analog-to-digital conversion module, a frequency mixing module, an extraction filter module, a Fourier transform module, a frequency measurement module, a scanning module and a selector.

The analog-to-digital conversion module receives an analog intermediate frequency signal to convert the analog intermediate frequency signal into a digital intermediate frequency signal.

An input end of the frequency mixing module is connected to an output end of the analog-to-digital conversion module to generate two orthogonal local carriers to convert the digital intermediate frequency signal to a digital baseband signal.

An input end of the extraction filter module is connected to an output end of the frequency mixing module to perform low-pass filtering and extraction of the digital baseband signal, so as to reduce a data rate.

An input end of the Fourier transform module is connected to an output end of the extraction filter module to obtain a frequency domain signal by performing discrete Fourier transform on a short data.

An input end of the frequency measurement module is connected to an output end of the Fourier transform module, to obtain a first frequency measurement value using three-point interpolation frequency measurement based on a maximum amplitude and two adjacent calculated values in a frequency domain signal of Fourier transform.

An input end of the scanning module is connected to an output end of the frequency measurement module, to calculate a maximum amplitude point by point according to Fourier transform by taking the first frequency measurement value as a center and performing step scanning in a scanning range, so as to obtain a scanned second frequency measurement value.

An input end of the selector is respectively connected to output ends of the frequency measurement module and the scanning module, to select either the first frequency measurement value or the second frequency measurement value as a result of frequency measurement.

The present disclosure further provides a high-precision frequency measuring method, including: performing analog-to-digital conversion of an analog intermediate frequency signal to generate a digital intermediate frequency signal; using a frequency mixing module to generate two orthogonal local carriers, and converting the digital intermediate frequency signal to a digital baseband signal; performing low-pass filtering and extraction of the digital baseband signal so as to reduce a data rate; obtaining a corresponding frequency domain signal by performing discrete Fourier transform of a short data; obtaining a first frequency measurement value using three-point interpolation frequency measurement based on a maximum amplitude and two adjacent calculated values in a frequency domain signal of Fourier transform; obtaining a scanned second frequency measurement value by calculating a maximum amplitude according to Fourier transform by taking the first frequency measurement value as a center and performing small frequency step in a scanning range; and selecting either the first frequency measurement value or the second frequency measurement value as a result of frequency measurement.

As described above, the high-precision frequency measuring system and method of the present disclosure has the following beneficial effects:

The method of three-point interpolation and fine scanning breaks through the limitation of data length on frequency measurement accuracy, and can obtain high frequency measurement accuracy even through short data; At the same time, by setting the bypass control and the either-or circuit, not only the flexibility of the entire system is enhanced, but also the waste of resources is avoided.

### BRIEF DESCRIPTION OF THE DRAWINGS

FIG. 1 is a block diagram showing the structure of a high-precision frequency measuring system provided by the present disclosure.

FIG. 2 is a block diagram showing the structure of an extraction filter module in the high-precision frequency measuring system in FIG. 1.

FIG. 3 shows the DFT amplitude sample of the frequency signal in the high-precision frequency measuring system in FIG. 1.

FIG. 4 shows a flow chart of a high-precision frequency measuring method provided by the present disclosure.

### DESCRIPTION OF COMPONENT REFERENCE SIGNS

1 Analog-to-digital conversion module
2 Frequency mixing module
3 Extraction filter module
4 Fourier transform module
5 Frequency measurement module
6 Scanning module
7 Selector
8 Parameter configuration module
9 Clock module
S1˜S7 Step 1 to Step 7

### DETAILED DESCRIPTION OF THE PREFERRED EMBODIMENTS

The embodiments of the present disclosure will be described below. Those skilled in the art can easily understand other advantages and effects of the present disclosure according to contents disclosed by the specification. The present disclosure can also be implemented or applied through other different specific embodiments. Various modifications or changes can also be made to all details in the specification based on different points of view and applications without departing from the spirit of the present disclosure. It needs to be stated that the following embodiments and the features in the embodiments can be combined with one another under the situation of no conflict.

It needs to be stated that the drawings provided in the following embodiments are just used for schematically describing the basic concept of the present disclosure, thus only illustrating components only related to the present disclosure and are not drawn according to the numbers, shapes and sizes of components during actual implementation, the configuration, number and scale of each component during actual implementation thereof may be freely changed, and the component layout configuration thereof may be more complex.

Referring to FIG. 1, the present disclosure provides a high-precision frequency measuring system, including: an analog-to-digital conversion module 1, a frequency mixing module 2, an extraction filter module 3, a Fourier transform module 4, a frequency measurement module 5, a scanning module 6 and a selector 7.

The analog-to-digital conversion module 1 receives an analog intermediate frequency signal to convert the analog intermediate frequency signal into a digital intermediate frequency signal.

An input end of the frequency mixing module 2 is connected to an output end of the analog-to-digital conversion module 1 to generate two orthogonal local carriers to convert the digital intermediate frequency signal to a digital baseband signal.

According to system requirements, sampling strategies such as oversampling or bandpass sampling may be adopted. When adopting oversampling strategy, the carrier frequency is the same as the analog intermediate frequency, and when adopting the bandpass sampling strategy, the carrier frequency should be consistent with the signal center frequency after bandpass sampling.

Additionally, the frequency mixing module includes a frequency source and a multiplier, and the frequency source is realized by a direct frequency synthesizer 21(DDS) to generate two orthogonal local carriers; the first mixing circuit 22 and the second mixing circuit 23 are respectively connected by two multipliers, so as to downconvert the digital intermediate frequency signal to the digital baseband signal.

An input end of the extraction filter module 3 is connected to an output end of the frequency mixing module 2 to perform low-pass filtering and extraction of the digital baseband signal, so as to reduce a data rate.

The first extraction filter module 31 and the second extraction filter module 32 perform low-pass filtering and extraction of the digital baseband signal. On the one hand, high frequency noise is filtered; on the other hand, the data rate is reduced; the selection of extraction multiple should ensure that the extracted signal spectrum will not be aliased.

An input end of the Fourier transform module 4 is connected to an output end of the extraction filter module 3 to obtain a frequency domain signal by performing discrete Fourier transform on a short data.

performing discrete Fourier transform (DFT) of short data (data with reduced rate) after frequency mixing, extraction and filtering within a short time by adopting the discrete Fourier transform (DFT) circuit and applying fast Fourier transform (FFT) algorithm on the discrete Fourier transform circuit.

An input end of the frequency measurement module 5 is connected to an output end of the Fourier transform module 4, to obtain a first frequency measurement value using three-point interpolation frequency measurement based on a maximum amplitude and two adjacent calculated values in a frequency domain signal of Fourier transform.

The frequency measurement module includes an amplitude sorting circuit and a three-point interpolation circuit, and the amplitude sorting circuit obtains the maximum amplitude by sorting amplitudes obtained by the discrete Fourier transform; the three-point interpolation circuit obtains the first frequency measurement value by using a variety of three-point interpolation algorithms based on the maximum amplitude and its two adjacent calculated values.

An input end of the scanning module 6 is connected to an output end of the frequency measurement module 5, to calculate a maximum amplitude point by point according to Fourier transform by taking the first frequency measurement value as a center and performing step scanning in a scanning range, so as to obtain a scanned second frequency measurement value.

The scanning module includes a fine scanning circuit, which calculates the maximum amplitude point according to the Fourier transform idea by taking the first frequency measurement value obtained by the three-point interpolation frequency measurement as the center and performing small frequency step in the scanning range, so as to obtain a corresponding second frequency measurement value.

An input end of the selector 7 is respectively connected to output ends of the frequency measurement module 5 and the scanning module 6, to select either the first frequency measurement value or the second frequency measurement value as a result of frequency measurement.

The selector is an either-or circuit, one of the fine measurement results based on the three point interpolation frequency measurement module and the scanning module is selected as the measurement result of the system, thus the function could enhance the flexibility of the system, and reduce the complexity of the system as much as possible by making appropriate choices according to actual requirements.

By setting the frequency measurement module and the scanning module, compared with the sweep frequency measuring method based on Fourier transform (DFT), the system provided by the present embodiment breaks through the limitation of data length on frequency measurement accuracy, and can obtain high frequency measurement accuracy even through short data.

Specifically, the high-precision frequency measuring system further includes: a parameter configuration module 8 and a clock module 9.

The parameter configuration module 8 performs parameter configuration on a data length in the Fourier transform module, an extraction multiple in the extraction filter module, a filter coefficient and a bypass selection circuit according to externally input configuration information.

The clock module 9 generates clock signals required by each module according to configuration information input externally.

In this embodiment, the parameter configuration module 8 and the clock module 9 are configured by externally input configuration information, which improves the flexibility of the entire system.

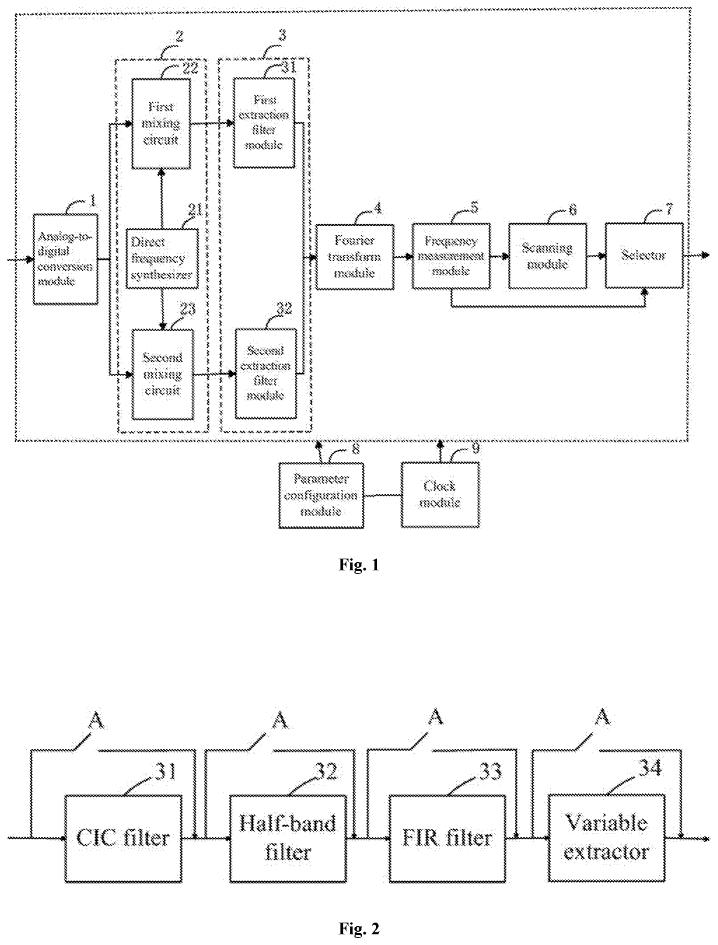

Referring to FIG. 2, which is a block diagram showing the structure of the extraction filter module in the high-precision frequency measuring system in FIG. 1.

The extraction filter circuit includes a cascaded integrator-comb (CIC) filter 31 CIC, a half-band filter 32HB (Half-Band Filter), a Finite Impulse Response (FIR) filter 33, a variable extractor 34 and a plurality of bypass selection circuits A. The cascaded integrator-comb filter 31, the half-band filter 32, the FIR filter 33 and the variable extractor 34 are end-to-end and sequentially connected. The cascaded integrator-comb filter 31, the half-band filter 32, the FIR filter 33 and the variable extractor 34 are all correspondingly connected in parallel with a bypass selection circuit A.

Specifically, in the present embodiment, the CIC filter 31 and the HB filter 32 can quickly extract the signal with the high data rate, causing the data rate to drop rapidly. Due to that the coefficients of CIC filter 31 are all 1, therefore, the hardware implementation is very simple with only addition and subtraction operation. However, the characteristics of the transition band and stop band attenuation are not very good. The extraction factor of the HB filter 32 is fixed at 2, and nearly half of its filter coefficients are zero, which can save half of the multipliers, and is very suitable for the application requirements where sampling rate is reduced by half. The FIR filter 33 is mainly used for implementing the channel shape filter, while the variable extraction circuit 34 can further reduce the data rate. Setting up the bypass selection circuit allows the system to be more flexible to meet a variety of application needs.

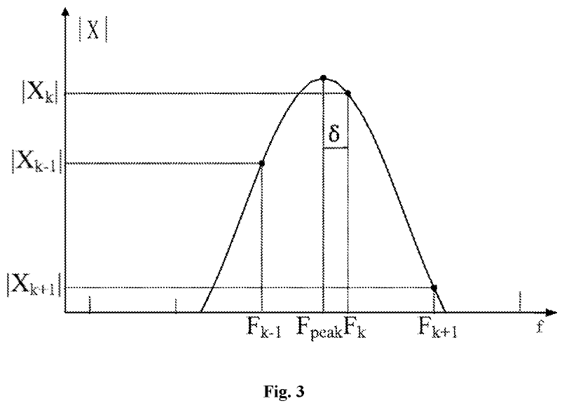

Referring to FIG. 3, which shows the DFT amplitude sample of the frequency signal in the high-precision frequency measuring system in FIG. 1, including: an amplitude sample of DFT transform before a single frequency point signal, wherein Fₖ represents the frequency corresponding to the point with the largest amplitude in the DFT operation result, Fₖ₊₁ and Fₖ₋₁ are its two adjacent calculated frequencies, Fₚₑₐₖ represents the true frequency of the signal, ideally between Fₖ₊₁ and Fₖ₋₁. In the classical frequency estimation algorithm, Fₖ is usually taken as the result of frequency estimation according to the result of Fourier transform, and the estimated highest accuracy of frequency can only reach the physical resolution of DFT, which is affected by the data length. In the present disclosure, a decimal correction term δ is obtained by using the three-point interpolation algorithm to represent the distance between Fₚₑₐₖ and Fₖ, and a more accurate estimation value of signal frequency, Fₚₑₐₖ, is finally obtained. Algorithms that can achieve three-point interpolation include those proposed by Jacobsen, Quinn and Macleod:

$$\begin{matrix}δ = \frac{P ( \vert {X}_{k + 1} \vert - \vert {X}_{k - 1} \vert )}{( \vert {X}_{k} \vert + \vert {X}_{k + 1} \vert + \vert {X}_{k - 1} \vert )} & ( 1 ) \\ δ = \frac{( \vert {X}_{k + 1} \vert - \vert {X}_{k - 1} \vert )}{( 4 \vert {X}_{k} \vert - 2 \vert {X}_{k - 1} \vert - 2 \vert {X}_{k + 1} \vert )} & ( 2 ) \\ δ = - Re [ \frac{( {X}_{k + 1} - {X}_{k - 1} )}{( 2 {X}_{k} - {X}_{k - 1} - {X}_{k + 1} )} ] & ( 3 ) \\ δ = - Re [ \frac{Q ( {X}_{k - 1} - {X}_{k + 1} )}{( 2 {X}_{k} + {X}_{k - 1} + {X}_{k + 1} )} ] & ( 4 )\end{matrix}$$

Wherein Xₖ, Xₖ₊₁, and Xₖ₋₁ in the equations (1) to (4) respectively represent the DFT calculation result corresponding to Fₖ, Fₖ₊₁ and Fₖ₋₁. Re represents the real part, P and Q represent variable constants used to adjust the effects of different window functions. The frequency estimation result of the three-point interpolation is obtained by the following equation:

Fₚₑₐₖ=Fₖ+δfₛ/N (5)

Where fₛ in the equation (5) is the sampling frequency, N is the number of points participating in the DFT operation, δ is the decimal correction term, Fₖ represents the frequency corresponding to the point with the largest amplitude in the DFT operation result, and Fₚₑₐₖ represents the true frequency of the signal.

In the present embodiment, the accuracy of the frequency measuring system is improved by the three-point interpolation algorithm, which breaks the limitation of the classical method, that is, the measurement resolution is proportional to the data length, and the method of increasing the resolution must increase the data length.

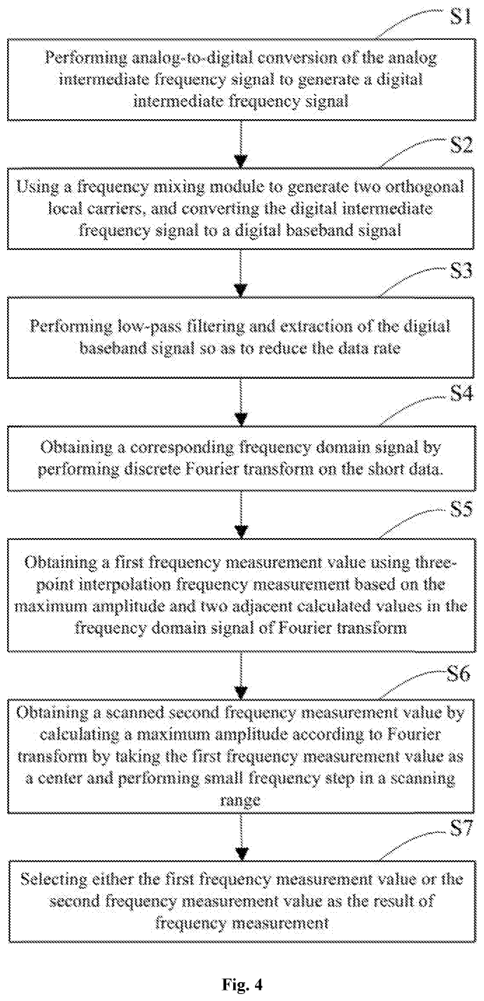

Referring to FIG. 4, which shows a flow chart of the high-precision frequency measuring method provided by the present disclosure, including: Step S1˜S7.

Step S1: performing analog-to-digital conversion of the analog intermediate frequency signal to generate a digital intermediate frequency signal.

Specifically, the input analog intermediate frequency signal can be converted by an analog-to-digital converter, such as an analog-to-digital conversion circuit S (ADC).

Step S2: using a frequency mixing module to generate two orthogonal local carriers, and converting the digital intermediate frequency signal to a digital baseband signal.

Specifically, the frequency mixing module can be used to process the digital intermediate frequency signal to obtain a digital baseband signal, which will not be repeated here.

Step S3: performing low-pass filtering and extraction of the digital baseband signal so as to reduce the data rate.

Specifically, an extraction filtering module may be used to filter and process the digital baseband signal to obtain short data.

Step S4: obtaining a corresponding frequency domain signal by performing discrete Fourier transform on the short data.

Specifically, a Fourier transform module may be used to perform discrete Fourier transform processing.

Step S5: obtaining a first frequency measurement value using three-point interpolation frequency measurement based on the maximum amplitude and two adjacent calculated values in the frequency domain signal of Fourier transform.

Specifically, the frequency measurement module can be used for processing.

Step S6: obtaining a scanned second frequency measurement value by calculating a maximum amplitude according to Fourier transform by taking the first frequency measurement value as a center and performing small frequency step in a scanning range.

Specifically, the scanning module can be used for processing.

Step S7: selecting either the first frequency measurement value or the second frequency measurement value as the result of frequency measurement.

Specifically, an either-or circuit can be adopted, and one of the two can be selected as the result of frequency measurement.

The specific manner of the step 6 is described in detail as follows:

Determining the scanning range and the scanning step m, taking the first frequency measurement value as the center in the scanning range; performing scanning calculations according to the following equation:

$$X [ m ] = {\sum }_{n = 0}^{N - 1} x [ n ] {e}^{\frac{- j 2 π mn}{N}} \qquad ( 6 )$$

In equation (6), x[n] is the data sequence, the frequency corresponding to the point with the largest amplitude in X[m] is the measurement result, m is a decimal, and its value represents the scanned frequency point.

In summary, the method of three-point interpolation and fine scanning adopted by the present disclosure breaks through the limitation of data length on frequency measurement accuracy, and can obtain high frequency measurement accuracy even through short data; At the same time, by setting the bypass control and the either-or circuit, not only the flexibility of the entire system is enhanced, but also the waste of resources is avoided. Therefore, the present disclosure effectively overcomes various shortcomings and has high industrial utilization value.

The above-mentioned embodiments are just used for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

1. A high-precision frequency measuring system, comprising:
an analog-to-digital conversion module, receiving an analog intermediate frequency signal to convert the analog intermediate frequency signal into a digital intermediate frequency signal;
a frequency mixing module, an input end of the frequency mixing module is connected to an output end of the analog-to-digital conversion module to generate two orthogonal local carriers to convert the digital intermediate frequency signal to a digital baseband signal;
an extraction filter module, an input end of the extraction filter module is connected to an output end of the frequency mixing module to perform low-pass filtering and extraction of the digital baseband signal, so as to reduce a data rate;
a Fourier transform module, an input end of the Fourier transform module is connected to an output end of the extraction filter module to obtain a frequency domain signal by performing discrete Fourier transform on a short data;
a frequency measurement module, an input end of the frequency measurement module is connected to an output end of the Fourier transform module, to obtain a first frequency measurement value using three-point interpolation frequency measurement based on a maximum amplitude and two adjacent calculated values in a frequency domain signal of Fourier transform;
a scanning module, an input end of the scanning module is connected to an output end of the frequency measurement module, to calculate a maximum amplitude point by point according to Fourier transform by taking the first frequency measurement value as a center and performing step scanning in a scanning range, so as to obtain a scanned second frequency measurement value; and
a selector, an input end of the selector is respectively connected to output ends of the frequency measurement module and the scanning module, to select either the first frequency measurement value or the second frequency measurement value as a result of frequency measurement.

2. The high-precision frequency measuring system according to claim 1, wherein the frequency mixing module comprises a frequency source and a multiplier, and the frequency source is realized by a direct frequency synthesizer to generate two orthogonal local carriers; the first mixing circuit and the second mixing circuit are respectively connected by two multipliers, so as to downconvert the digital intermediate frequency signal to the digital baseband signal.

3. The high-precision frequency measuring system according to claim 1, wherein the extraction filter circuit comprises a cascaded integrator-comb filter, a half-band filter, a FIR filter, a variable extractor and a plurality of bypass selection circuits, wherein the cascaded integrator-comb filter, the half-band filter, the FIR filter and the variable extractor are end-to-end and sequentially connected, and the cascaded integrator-comb filter, the half-band filter, the FIR filter and the variable extractor are all correspondingly connected in parallel with a bypass selection circuit.

4. The high-precision frequency measuring system according to claim 1, wherein the frequency measurement module comprises an amplitude sorting circuit and a three-point interpolation circuit, and the amplitude sorting circuit obtains the maximum amplitude by sorting amplitudes obtained by the discrete Fourier transform; the three-point interpolation circuit obtains the first frequency measurement value by using a three-point interpolation algorithm based on the maximum amplitude and its two adjacent calculated values.

5. The high-precision frequency measuring system according to claim 1, wherein the scanning module includes a fine scanning circuit, which calculates the maximum amplitude point according to Fourier transform by taking the first frequency measurement value obtained by the three-point interpolation frequency measurement as the center and performing small frequency step in the scanning range, so as to obtain a corresponding second frequency measurement value.

6. The high-precision frequency measuring system according to claim 1, wherein the selector includes an either-or circuit.

7. The high-precision frequency measuring system according to claim 1, further comprising: a parameter configuration module, performing parameter configuration on a data length in the Fourier transform module, an extraction multiple in the extraction filter module, a filter coefficient and a bypass selection circuit according to externally input configuration information.

8. The high-precision frequency measuring system according to claim 1, further comprising: a clock module, generating clock signals required by each module according to configuration information input externally.

9. A high-precision frequency measuring method, comprising:
performing analog-to-digital conversion of an analog intermediate frequency signal to generate a digital intermediate frequency signal;
using a frequency mixing module to generate two orthogonal local carriers, and converting the digital intermediate frequency signal to a digital baseband signal;
performing low-pass filtering and extraction of the digital baseband signal so as to reduce a data rate;
obtaining a corresponding frequency domain signal by performing discrete Fourier transform of a short data;
obtaining a first frequency measurement value using three-point interpolation frequency measurement based on a maximum amplitude and two adjacent calculated values in a frequency domain signal of Fourier transform;
obtaining a scanned second frequency measurement value by calculating a maximum amplitude according to Fourier transform by taking the first frequency measurement value as the center and performing small frequency step in a scanning range; and
selecting either the first frequency measurement value or the second frequency measurement value as a result of frequency measurement.

10. The high-precision frequency measuring method according to claim 9, wherein obtaining the scanned second frequency measurement value by calculating the maximum amplitude according to Fourier transform by performing small frequency step in the scanning range comprises:
determining the scanning range and a scanning step m, taking the first frequency measurement value as the center in the scanning range; performing scanning calculations according to the following equation:
$$X [ m ] = {\sum }_{n = 0}^{N - 1} x [ n ] {e}^{\frac{- j 2 π mn}{N}} \qquad ( 6 )$$
wherein x[n] is a data sequence, a frequency corresponding to a point with a largest amplitude in X[m] is a measurement result, m is a decimal, and its value represents a scanned frequency point.
